(19) United States
(12) Patent Application Publication
(10) Pub. No.: US 2008/0029757 A1
(43) Pub. Date: Feb. 7, 2008

(54) Semiconductor device having a laterally injected active region

(75) Inventors: Lawrence C. West, San Jose, CA (US); Francisco A. Leon, Palo Alto, CA (US)

Correspondence Address: WILMERHALE/BOSTON, 60 STATE STREET, BOSTON, MA, 02109, US

(73) Assignee: Applied Materials, Inc., Santa Clara, CA (US)

(21) Appl. No.: 11/599,197

(22) Filed: Nov. 14, 2006

Related U.S. Application Data
(60) Provisional application No. 60/736,480, filed on Nov. 14, 2005.

(51) Int. Cl. H01L 29/06

(52) U.S. Cl. 257/14; 257/E29.005

(57) ABSTRACT

A semiconductor device including: a quantum well having photon emission energy level, the quantum well having at least one active layer and two barrier layers, one disposed above the active layer and one disposed below the active layer; and injection regions for injecting electrons into the quantum well, wherein the electrons are cool electrons with respect to the active layer of the quantum well.

### CROSS-REFERENCE TO RELATED APPLICATIONS

This application claims the benefit of U.S. Provisional Application No. 60/736,480, entitled “Semiconductor Device Having a Laterally Injected Active Region” filed on Nov. 14, 2005.

This application makes reference to co-pending U.S. Provisional Patent Application No. 60/731,201, entitled “Semiconductor Laser” filed on Nov. 14, 2005; and U.S. Provisional Patent Application No. 60/736,202, entitled “Pinch Waveguide” filed on Nov. 14, 2005, the contents of both of which are incorporated herein by reference.

### FIELD OF THE INVENTION

The present invention relates to active material or quantum well structures, and more particularly, to the injection of electrons into the active material or quantum well structures.

### DESCRIPTION OF THE PRIOR ART

Lasers, in general, require a method for providing photon gain to an optical cavity or resonator to allow for lasing. Photon or optical gain is required to support continued lasing from the optical cavity. Optical gain is the process whereby more photons are being emitted or created than are being absorbed in the active material or quantum well.

A traditional method of providing optical gain is to do so via an active region or quantum well which is enclosed in an optical cavity. In a quantum well, electrons are encouraged to interact with electron holes (hereafter “holes”) via exposure to a potential. The resulting recombination produces energy in the form of photons. When the created photons are greater in number than the number of photons being absorbed, there is an optical emission or lasing.

Quantum wells for semiconductor lasers, often times, are located between electrodes disposed above and below the quantum wells. Generally, these electrodes are formed from a material having an N type dopant, i.e., a material having a high density of electrons, and a material having a P type dopant, i.e., a material having a high density of holes. An external potential is applied at the N type electrode and causes a differential between the N type electrode and the P type electrode. This differential forces the electrons from the N-material and holes from the P-material to interact in the quantum well. When an electron nears a hole, the electron falls into the hole, i.e., electron-hole pairing, and energy is released in the form of a photon as well as heat.

However, photons are produced by the recombination of electrons and electron-holes at a specific energy level in the quantum well. These energy levels are determined by the material characteristics of the quantum well. It takes time for the electrons to reach the correct energy level for the particular quantum well. Thus, the electrons, when first introduced into the quantum well, occupy energy levels in the quantum well that do not support the recombination of holes with the electrons. In other words, a majority of the electrons enter the quantum well at energy levels which are too high for recombination to initially take place. Generally, these electrons are injected at an energy level associated with the barrier layer of the quantum well. However, the electrons at the higher energy levels will naturally distribute energy due to electron and lattice scattering effects and dissipate energy from inelastic collisions with electrons and phonons with the dissipated energy showing up as heat in the semiconductor lattice. Thus, the electrons will eventually occupy a lower energy level, i.e., an energy level whereby recombination with the holes can occur. This lower energy level is associated with the active material in the quantum well.

It is this elapsed time, the time for the injected electrons to reach the correct energy level, as referenced in an article by Robert M. Spencer, et al., entitled “High Speed Direct Modulation of Semiconductor Lasers,” that is a limiting factor to creating faster and more efficient semi-conductor lasers. In other words, semiconductor applications require very fast on off cycling and very fast intensity cycling. Accordingly, the amount of time required for a threshold optical gain to be created, i.e., threshold is where lasing begins, or the amount of time additional gain can be created to advance intensity is limited by the time it takes the injected electrons to reach the lower energy level associated with the active material in the quantum well.

Accordingly, there is a need for an improved semiconductor laser which reduces the time for an electron to reach the appropriate energy level associated with the active material to allow combination of electron-hole pairs.

### SUMMARY OF THE INVENTION

The embodiments described herein represent an improved semiconductor laser having a quantum well design whereby electrons are injected at a predetermined energy level whereby they can immediately recombine with holes to create photons. To provide an improved semiconductor laser electrons are injected laterally into a quantum well.

In general, in ones aspect the invention features a semiconductor device including: a quantum well having photon emission energy level, the quantum well having at least one active layer and two barrier layers, one disposed above the active layer and one disposed below the active layer; and injection means for injecting electrons into the quantum well, wherein the electrons are cool electrons with respect to the active layer of the quantum well.

In general, in another aspect, the invention features a semiconductor device which includes: a quantum well, the quantum well having at least one active layer and two barrier layers, one disposed above the active layer and one disposed below the active layer; and means for injecting electrons laterally into the quantum well, the electrons having an effective conduction band energy similar to the active layer in an emission region of the semiconductor device.

In general, in still another aspect, the invention features a method for injecting electrons into a semiconductor device having an active region involving: providing a source of electrons; and injecting the electrons into the active region, wherein the electrons are cool electrons with respect to the active region.

In general, in still yet another aspect, the invention features a method for injecting electrons into a semiconductor device having an active region involving: providing a source of electrons; and injecting the electrons laterally into the active region, wherein the electrons have an effective temperature which is between 1 and 2 times the temperature of the active region lattice.

In general, in another aspect the invention features a semiconductor device including: an active region having photon emission energy level; and injection means for injecting electrons at a predetermined energy level into the active region, the predetermined energy level corresponding to an energy level associated with the recombination of electrons with holes in the active region.

In general, in still another aspect, the invention features the present invention a semiconductor device including: an active region having photon emission energy level; and injection means for injecting electrons, the emission means comprising a first region having a first conductivity type and a second region having a second conductivity type the first region disposed laterally from the active region by less than or equal to 50 nm and the second region disposed distal from the first region and laterally disposed from the active region by less than or equal to 50 nm.

Other objects and features of the present invention will be apparent from the following detailed description of the preferred embodiment.

### BRIEF DESCRIPTION OF THE DRAWINGS

The invention will be described in conjunction with the accompanying drawings, in which:

FIG. 1A illustrates a schematic cross sectional view of a conventional quantum well structure in which electrons are perpendicularly injected into a quantum well.

FIG. 1B illustrates an initial energy band diagram for the quantum well structure of FIG. 1A.

FIG. 2A illustrates a schematic cross sectional view a quantum well structure.

FIG. 2B illustrates an initial energy band diagram of the quantum well structure FIG. 2A.

FIG. 3 illustrates a schematic cross sectional view of another quantum well structure.

FIG. 4 illustrates a schematic cross sectional view of an active material.

FIG. 5A illustrates the valance and transition bands for the active material illustrated in FIG. 4.

FIG. 5B illustrates the valance and transition bands for the active material for a prior art device.

### DETAILED DESCRIPTION OF THE PREFERRED EMBODIMENT

There are two significant limiting factors associated with conventional semiconductor lasers: 1) elapsed time for change in optical power, and 2) heat associated with the device and the effect of this heat on quantum effects in the active region. The first limiting factor, i.e., the amount of time that it takes for the active region to produce optical gain, has been a subject of exploration by prior researchers for some time. This first limiting factor is particularly troublesome with regard high speed semiconductor lasers since the goal of these lasers is to reduce switching time. The second limiting factor, i.e., the effect of heat in quantum devices is just beginning to surface as a subject of exploration as devices become smaller, hotter, and faster. Both of these limiting factors are discussed in greater detail below.

The two purposes for creating optical gain in the active region of laser are: 1) to create enough optical gain to cause the laser to lase, referred to as threshold gain, and 2) to create enough additional optical gain to cause the laser to increase output intensity. Thus, the time it takes to create a sufficient number of photons in the active region is directly related to the time that a laser can be cycled on and off and the time it takes to cycle from one intensity level to another level.

A traditional method of providing optical gain is to do so via an active region such as a quantum well. In a quantum well, electrons are encouraged to interact with holes via exposure to an electric field or potential applied to the active material. The resulting interaction produces energy in the form of photons. When the number of photons being created is greater than the number of photons being absorbed, there is optical gain.

Quantum wells for conventional semiconductor lasers are located between electrodes disposed above and below the quantum wells. Generally, these electrodes are formed from a material having an N type dopant, i.e., a material having a high density of electrons, and a material having a P type dopant, i.e., a material having a high density of holes. An external potential is applied at the N type electrode and causes a differential between the N type electrode and the P type electrode. This differential forces the electrons from the N-material and holes from the P-material to interact in the active layers of the quantum wells. When an electron nears a hole, the electron is captured by the hole, i.e., electron-hole pairing, and energy is released in the form of a photon as well as heat.

Photons are produced by the combination of holes and electrons residing at a specific energy level, i.e., the photon emission energy level of the quantum well. The photon emission energy level of a particular quantum well is based on, among other things: the active material used for the quantum well, the size of the quantum well, the shape of the quantum well, the structure of the quantum well, and the bandgap between the active material and the barrier layers, etc.

Electrons, when first introduced into a quantum well, may occupy energy levels higher than the photon emission energy level. These higher energy levels are associated with the barrier layers. Many such “hot electrons” may eventually distribute energy due to electron and lattice scattering effects and dissipate energy from inelastic collisions with electrons and phonons with the dissipated energy showing up as heat in the semiconductor lattice and thus become “cool electrons.” the process of distributing and dissipating energy has the adverse consequence of generating heat and may also take a considerable amount of time. Both of these side effects are undesirable because they are detrimental to device performance.

In conventional quantum well structures, even when cool electrons are initially produced at the N type material electrode, these cool electrons are converted into hot electrons when the electrons enter the quantum well. When cool electrons from the N-material traverse one of the quantum well barriers, either the upper or lower boundary of the quantum well, the cool electrons may scatter or “fall” into the quantum well and kinetic energy is generated and captured by the “falling” electrons. Thus, the energy gained by the cool electrons in the barrier layer converts the cool electrons into hot electrons in the active layer. This is a very undesirable result of conventional quantum well structures.

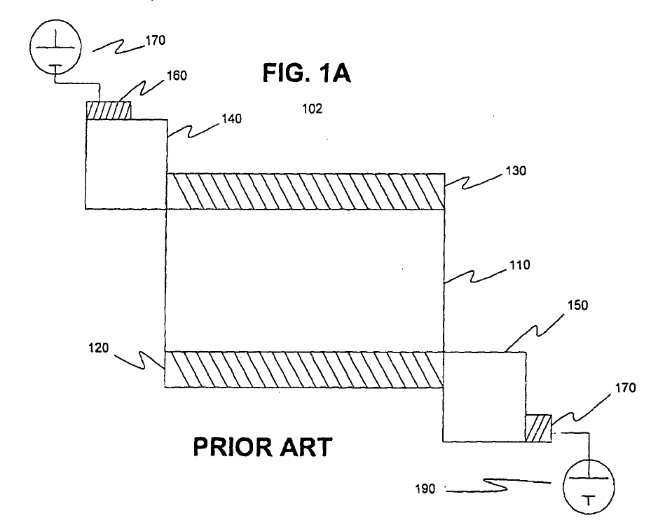

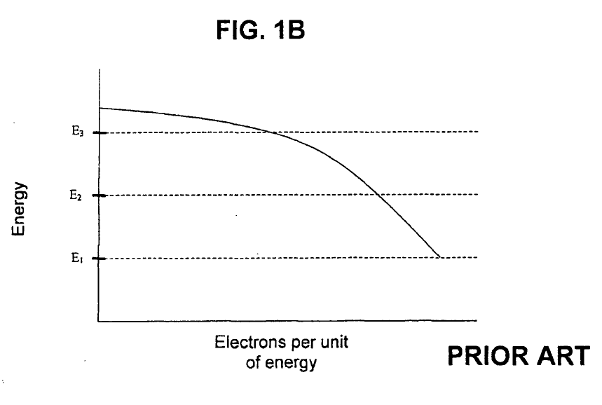

FIG. 1A illustrates a conventionally designed quantum well structure 102 with substantially perpendicularly introduced electrons and holes (not shown). Quantum well structure 102 includes a quantum well 110 disposed between a lower barrier 120 and an upper barrier 130 layers. Upper barrier layer 130 is adjacent to an N-type material region 140 and lower barrier layer 120 is adjacent to a P-type material region 150. A metal connector 160 provides an interface to a high voltage source 170 and metal connector 180 provides an interface to a low voltage source 190. The voltage difference between high voltage source 170 and low voltage source 190 is such that current will flow from high voltage source 170 to low voltage source 190.

When a voltage differential is created between high voltage source 170 and low voltage source 190, current will follow the path of the least resistance, i.e., from voltage source 170 to voltage source 190. The materials represented in FIG. 1A are designed in such a way so that the electrons will flow from the N-type material across upper barrier and fall down into the quantum well. In falling from the energy level of the upper barrier, the electrons receive additional energy, i.e., kinetic energy. The electrons then occupy different energy levels within the quantum well, due to the increased energy. After a period of time, the electrons dissipate energy, and then cool down to eventually occupy the first energy level. Once the electrons enter the first energy level, they then recombine with the waiting holes and produce photons. After a period of time, sufficient photons are created so that enough optical gain is created to reach threshold intensity and the device lazes.

FIG. 1B is a graphical representation of electron population as a function of energy within the conventional quantum well as illustrated in FIG. 1A. The sample quantum well is able to support three energy levels, E1, E2, and E3. Electrons that ultimately occupy energy level E1 are able to combine with the holes, provided by the P-type material. When the electrons are initially injected into the quantum well, many of the electrons occupy upper energy levels E3 and E2. These electrons have an effective temperature substantially similar to the temperature corresponding to the energy level associated with penetrating the barrier layer. By substantially, we mean within 2% of the temperature corresponding to the energy of the barrier. After a period of time, the electrons will dissipate their energy and drop down to occupy energy level E1, i.e., have an effective temperature which is between 1 and 2 times the temperature of the active material.

Conventional semiconductor lasers employ a quantum well structure design in which a current field is applied substantially perpendicular to the quantum well. Accordingly, the electrons are required to first traverse the quantum well barrier in order to enter the quantum well. After a period of cooling down, a sufficient number of cool electrons are created and these cool electrons eventually occupy the photon emission energy level and enough optical gain will be created to achieve threshold gain.

In the described embodiment, cool charge carriers are injected directly into the quantum well, thereby avoiding any increase in energy due to traversing the quantum well barrier. The cool electrons/holes that are directly injected into the quantum well may immediately combine with respective holes/electrons and, thereby, rapidly and efficiently produce photons. That is, the electrons are injected into the quantum well at the energy level where they may immediately combine with the holes.

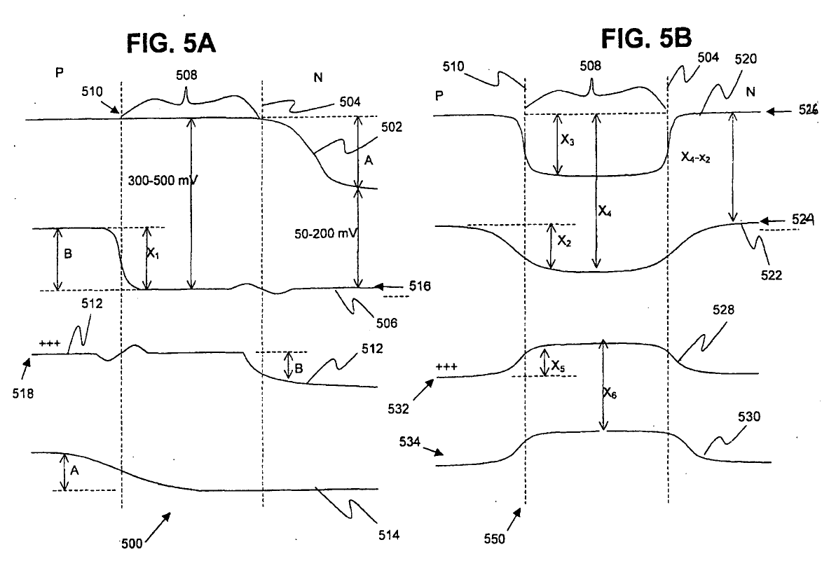

It should be understood that the term “cool charge carrier” includes “cool electrons or holes” as well as “cold electrons or holes.” “Cool electrons” are electrons that have an effective temperature significantly less than the temperature corresponding to the energy difference between the active layer and the barrier layer (the term “significantly” should be understood to mean 50% or more). Effective energy is defined by average electron energy divided by Boltzman's constant. This energy difference is illustrated in FIG. 5B as element X₄. Electrons are within the definition of cool so long as they have an effective temperature that is at least 2% less than the temperature corresponding to the energy difference between the energy associated with the active layer and the effective energy associated with the barrier layer. The phrase “effective energy” means the energy level that allows the electrons to penetrate the barrier layer. Alternatively, “cool electrons” are those with an effective temperature which is between 1 and 2 times the temperature of the active material lattice in the absence of a barrier layer disposed in the lattice. For clarity, the present discussion focuses on “electrons” but it should be understood that the term “holes” may be used interchangeably as long as the charge of the carrier is taken into account. Thus, a similar definition, modified to take into account the charge, would also apply for “cool holes.”

Also, in the described embodiment, the electrons are injected laterally into the quantum well. It should be understood that the term “laterally injected” refers to electrons which are provided to an active region via electrodes disposed horizontally with respect to the active region.

One desirable consequence to lateral injection is that the quantum well has little or no barrier between the N type electrode and the quantum well. Accordingly, the laterally injected electrons do not have to traverse the upper barrier of the quantum well and thus electrons do not receive an increase in kinetic energy from traversing the upper barrier of the quantum well. Thus, the laterally injected electrons immediately occupy the energy level required to recombine with the holes.

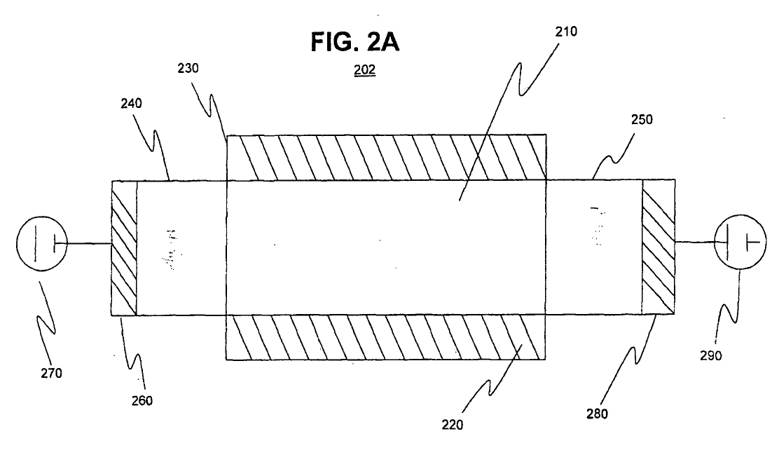

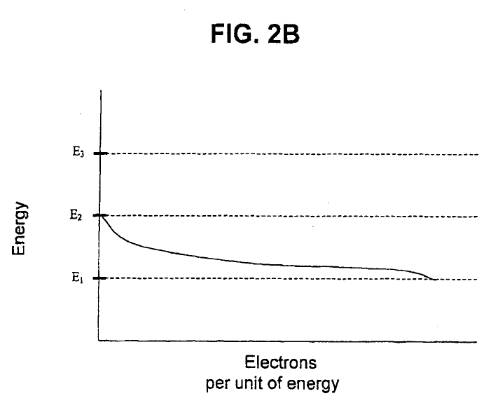

FIG. 2A illustrates a cross sectional view a quantum well structure 202 with laterally injected electrons. FIG. 2A includes a quantum well 210 bordered by a lower barrier layer 220 and an upper barrier layer 230. Upper barrier layer 230 is adjacent to an N-type material region 240 and lower barrier layer 220 is adjacent to P-type material region 250. A metal connector or electrode 260 provides an interface to a high voltage source 270 and a metal connector or electrode 280 provides an interface to a low voltage source 290. The voltage difference between high voltage source 270 and low voltage source 290 is such that current will flow from high voltage source 270 to low voltage source 290.

When a voltage differential is created between high voltage source 270 and low voltage source 290, current follows a path of the least resistance, i.e., from electrode 270 to electrode 280. The materials represented in FIG. 2A are designed in such a way that the electrons will flow from N-type material immediately into the quantum well. Known or existing spatial confinement means may be used to channel the electrons into quantum well 210. However, since the electrons enter quantum well 210 unimpeded, the electrons receive no increase in energy as they transition from the N-type material into quantum well 210. The electrons then occupy an energy level associated with the respective energy level for lasing in quantum well 210. In the described embodiment, the electrons have an energy level that is associated with the energy level whereby they most readily recombine with holes, i.e., the first energy level. The holes migrate into the quantum well as a result of the applied current.

Since a majority of the electrons are cold, they are immediately available to recombine with the holes. There is little to no elapsed time whereby electrons need to or are required to dissipate energy (and drop from a higher energy level). After a period of time, sufficient photons are created so that enough optical gain is created to reach threshold intensity. This period of time is substantially shorter than the that of the aforementioned conventional scenario of FIG. 1A.

FIG. 2B is a graphical representation of electron population as a function of energy within the quantum well structure 210 illustrated in FIG. 2A. FIG. 2B illustrates an initial energy band diagram of electrons as introduced according to the quantum well 210 as illustrated in FIG. 2A. The quantum well is able to support three energy levels, E1, E2, and E3. When the electrons are initially introduced (or injected) into quantum well 210, a majority of the electrons occupy energy level E1, which is in sharp contrast to the energy levels occupied by the initial population of electrons of the aforementioned conventional scenario of FIG. 1A.

The specific structure illustrated in FIG. 2A is merely exemplary of a generic quantum well which utilizes the concepts described herein. The specific location of the P-type and N-type material may vary so long as a portion of each material is lateral to the active region. The use of metal electrodes in communication with the P-type and N-type of material may be replaced by any type of electrode in the electrical arts. In addition, there may be more or fewer layers above or below the active region.

In fact, even laterally injected electrons face the same problems when the electrons are laterally injected into the barrier layer of a quantum well. An example of such a device is taught by U.S. Pat. No. 4,644,553, to Van Ruyven et al., for a Semiconductor Laser with Lateral Injection. The '533 patent teaches the direct injection of electrons into the barrier layers of a quantum well has the beneficial effect of increasing overall cavity efficiency by trapping electrons and holes in the quantum well. The unfortunate side effect of this approach is to inject hot electrons, as may be seen in FIG. 2 of the '533 patent, as electrons which enter the quantum well at the energy level associated with plane 16 and end at the energy level associated with plane 17. This corresponds to the bandgap between the aluminum phosphide barrier layers 5 and is illustrated by element 15. The present invention relates to the energy bandgap of the active layer which is illustrated by element 14.

This concept is illustrated in FIGS. 5A and 5B. FIG. 5A illustrates, via chart 500, the conduction and valance bands for a device constructed in accordance with the principles described herein. FIG. 5B illustrates, via chart 550, the conduction and valance bands for the device taught by the '533 patent.

Turning now to FIG. 5A, conduction band for barrier layer is illustrated by curve 502. As may be seen, the energy level of curve 502 is reduced in the region of the N-type material. As curve 502 approaches first heterojunction 504, the bandgap energy increases and then is constant through the rest of the device. The conduction band for the active layer is illustrated by curve 506. As may be seen, the energy level of curve 506 is constant between the region of the N-type material and emission region 508. Emission region 508 is defined between first heterojunction 504 and second heterojunction 510. There is a minor perturbation of curve 506 at first heterojunction 504. Curve 506 rises quickly upon exiting emission region 508 at second heterojunction 510. This substantial rise in energy is illustrated by variable X₁. Since the increase in energy associated with variable X₁ is significant, electrons entering the active region of the quantum well are confined within the quantum well. In the described embodiment, the voltage differential between curve 502 and 506 will be between 50 and 200 mv in the N-type material and between 300 and 500 mv in the emission region. Electrons 516 are injected at an energy level corresponding to the conduction level of the N-type material which also corresponds to the conduction level of the active material in the emission region 508. Thus, these are “cold electrons.”

The valance band for active layer is illustrated by curve 512. As may be seen, the energy level of curve 512 is reduced in the region of the N-type material. As curve 512 approaches second heterojunction 510, there is a minor perturbation of curve 506 at first heterojunction 504. The bandgap energy is constant through the emission region and then decreases near first heterojunction 504. This decrease effectively captures holes in the active layer of the quantum well. The valance band for the barrier layer is illustrated by curve 514. As may be seen, the energy level of curve 514 is constant between the region of the N-type material and emission region 508. Curve 514 rises quickly upon exiting emission region 508 at second heterojunction 510. Holes 518 are injected at an energy level corresponding to the valance level of the P-type material which also corresponds to the valance level of the active material in the emission region 508. Thus, these are “cold holes.”

One surprising result from the investigation of the use of cold electrons was that the energy associated with variable X₁ is significantly greater than that of prior art devices (illustrated as X₂ in FIG. 5B). This results in significantly more electrons being confined in the quantum well.

To truly appreciate the principles described herein, one must compare the conduction and valance bands for the device taught by the '533 patent with that of the present device. Therefore, we will describe these bands in detail below.

Tuning now to FIG. 5B, conduction band for a prior art barrier layer is illustrated by curve 520. As may be seen, the energy level of curve 520 is reduced in the region of the N-type material. As curve 520 approaches first heterojunction 504, the bandgap energy decreases in the emission region 508 and then increases back to the prior level at second heterojunction 510. This change in energy is illustrated by variable X₃ which is significant in the '533 patent. The conduction band for the prior art active layer is illustrated by curve 522. As may be seen, the energy level of curve 522 is constant between the region of the N-type material and emission region 508 and then drops by variable X₂ in emission region 508 and climbs by variable X₂ in the P-type material. Since variable X₁ is greater than variable X₂, confinement of electrons is greater in the embodiment illustrated by FIG. 5A. Electrons 524 and 526 are injected at an energy level corresponding to the conduction level either of the active layer in the N-type material or of the barrier layer in the N-type material. In either case, for electron-hole pairing, the electrons must drop an energy level indicated by variable X₂ or variable X₄, respectively. Thus, these are “hot electrons.”

The valance band for the prior art active layer is illustrated by curve 528. As may be seen, the energy level of curve 528 is reduced in the regions of the N-type and P-type materials. As curve 528 approaches second heterojunction 510, there is an energy increase of variable X₅. The bandgap energy is constant through the emission region and then decreases near first heterojunction 504. This decrease captures holes in the active layer of the quantum well. The valance band for the prior art barrier layer is illustrated by curve 530. As may be seen, the energy level of curve 530 is similar to curve 528. Holes 552 and 534 are injected at an energy level corresponding to the valance level of the P-type material which does not correspond to the valance level of the active material in the emission region 508. Thus, these are “hot holes.”

Examples of specific implementations will now be presented.

### EXAMPLE I

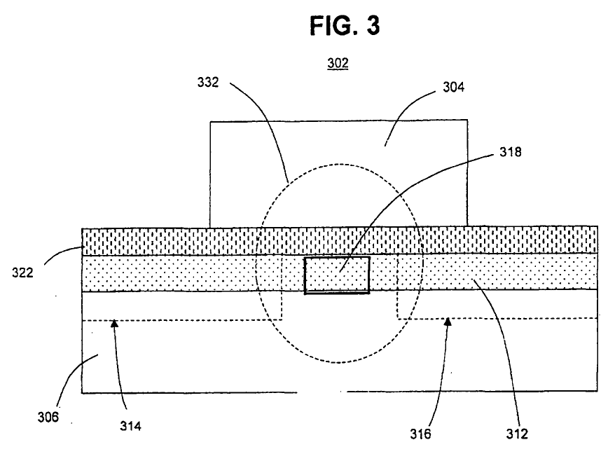

FIG. 3 illustrates a quantum well structure 302 that includes an ultra high confinement waveguide 304 made of silicon and a substrate 306 made of indium phosphide. The term “ultra high confinement waveguide” refers to a wave guide having high confinement of a primary mode within the waveguide. An example of an ultra high confinement waveguide is provided in U.S. Pat. No. 6,051,445 to Dubey et al., which is hereby incorporated in its entirety by reference.

Ultrahigh confinement waveguide 304 is coupled to a 130 nm active multi-quantum well region 312 that has a refractive index of ˜3.5 that is only slightly lower than the refractive index of ˜3.5 to 3.7 of ultra high confinement waveguide 304. P-type doped region 314, which acts as a P-type electrode, and N-type doped region 316, which acts as an N-type electrode, are located on the left and right side of an active region 318, respectively. Electrons and holes (not shown) are laterally confined in active region 318 between P-doped region 314 and N-doped region 316. Electrons and holes are laterally confined by a 70 nm ohmic contact 322 and substrate 306, each of which has a higher bandgap than active region 318, so the electron and hole charge carriers will fall into and stay in multi-quantum well region 312. Waveguide light is produced in waveguide light region 332.

Doping of the P-type doped region 314 and the N-type doped region 316 is performed by ion implanting with masks rather than by incorporating dopant during growth. However, a broad low-level P-type doping may be made in the multi-quantum well region to assist in carrier transport and laser operation. The N-type ion implantation is made at a concentration that is many times higher than the low level P-type doping in order that the net reduction in free electron charge in the N-type region is kept to a minimum.

High levels of ion implanting may cause the multi-quantum well region to disorder, but high quality quantum wells are not essential for good optical properties in the electrode regions and thus may assist with optical confinement of the device. The reduction in conductivity caused by disorder may be compensated by extra high doping and thicker regions of gain.

The extra width of the quantum wells provided by using laterally oriented electrodes provides extra area for carrier capture and a greater region for electron energy to dissipate for lower electron temperatures and higher speed.

The parasitic capacitance between the N and P type materials is reduced and current spread is greatly reduced, even to near zero, in a quantum well structure such as shown in FIG. 3. Parasitic capacitance is defined as the stored charge divided by the applied voltage. Current spread refers to electrons spreading out from the desired active region.

An important consideration in making a quantum well structure such as shown in FIG. 3 is how far the implanted donor and acceptors diffuse. In a shallow doping, with a peak doping about 70 nm deep at the surface between the ohmic contact and the quantum well, the later spread during implant will generally be low. Therefore, lateral diffusion during annealing of the quantum well structure may be important. However, the amount of lateral diffusion may be determined by one mask with multiple lithographic separations between N-type and P-type regions, and repeated anneal cycles until the performance of the quantum well structure is optimized.

### EXAMPLE II

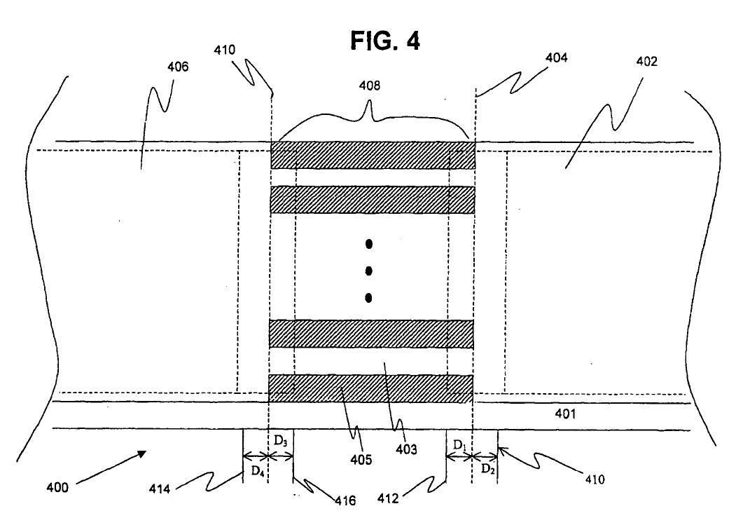

Turning now to FIG. 4, a prophetic example is provided for a generic class of laterally injected semiconductor devices 400. As may be seen, semiconductor device 400 comprises a substrate 401. In the described embodiment, substrate 401 is a semiconductor material such as InP. Alternating layers of active material 403 and barrier layers 405 are provided. Typically, active material is a semiconductor material such as InGaAs and barrier layers are a semiconductor materials such as InAlGaAs. Alternatively, active material could be a semiconductor material such as GaAs and barrier layers could be a semiconductor material such as AlGaAs. The number of quantum wells formed are merely a matter of design choice for the specific device. This is illustrated by the three dots in the emission region 408. Emission region 408 is defined between first heterojunction 404 and second heterojunction 410. A first electrode is formed by having a material of a first conductivity type disposed in region 402. Similarly, a second electrode is formed by having a material of a second and opposite conductivity type disposed in region 406. Typically, region 402 would be an N-type material and region 406 would be a P-type material. As may be seen, region 402 may have a border which extends from segment 410 to segment 412. Thus, the N-type material may blend into the emission region 408 and extend therein by a distance D₁). In this described embodiment, distance D1 is kept to a minimum in order to prevent defect from being formed in the emission region 408. The border may be laterally disposed from the first heterojunction 404 by a distance D₂. (e.g. where D₂ is ≦50 nm). Distance D₂ is critical in that if segment 410 is laterally displaced more than D₂, then any electrons that are injected will not be “cold electrons.”

As may be seen, region 406 may have a border which extends from segment 414 to segment 416. Thus, the P-type material may blend into the emission region 408 and extend therein by a distance D₃. In a preferred embodiment, distance D₃ is kept to a minimum in order to prevent defect from being formed in the emission region 408. It should be appreciated that the border may be laterally disposed from second heterojunction 410 by a distance D₄ (e.g. where D₄ is ≦50 nm). Distance D₄ is critical in that if segment 414 is laterally displaced more than D₄, then any holes that are injected will not be “cold holes.”

Other embodiments are within the following claims.

What is claimed is:

1. A semiconductor device comprising:
a quantum well having photon emission energy level, said quantum well having at least one active layer and two barrier layers, one disposed above said active layer and one disposed below said active layer; and
injection regions for injecting electrons into said quantum well, wherein said electrons are cool electrons with respect to the active layer of said quantum well.

2. The semiconductor device of claim 1, wherein said injection regions inject said electrons laterally into said quantum well.

3. The semiconductor device of claim 2, wherein said injection regions comprise an material having a first conductivity type and located laterally with respect to said quantum well, said injection region defining an emission region in said semiconductor device.

4. The semiconductor device of claim 1, wherein said electrons have an effective temperature below the temperature corresponding to the energy of said barrier layers.

5. The semiconductor device of claim 4, wherein said electrons have an effective temperature 90% or less than the temperature corresponding to the energy of said barrier layers.

6. The semiconductor device of claim 1, wherein substantially all of said electrons are cool electrons with respect to said quantum well.

7. A semiconductor device comprising:
a quantum well, said quantum well having at least one active layer and two barrier layers, one disposed above said active layer and one disposed below said active layer; and
a region for injecting electrons laterally into said quantum well, said electrons having an effective conduction band energy similar to the active layer in an emission region of said semiconductor device.

8. The semiconductor device of claim 7, wherein said injection region comprises a material having a first conductivity type and located laterally with respect to said quantum well.

9. The semiconductor device of claim 7, wherein said electrons are cool electrons with respect to the active layer of said quantum well.

10. The semiconductor device of claim 7, wherein substantially all of said electrons are cool electrons with respect to the active layer of said quantum well.

11. A method for injecting electrons into a semiconductor device having an active region comprising the steps of:
providing a source of electrons; and
injecting said electrons into said active region, wherein said electrons are cool electrons with respect to said active region.

12. The method of claim 11, wherein said electrons are injected laterally into said active region.

13. The method of claim 12, said injected electrons are injected into a material having a first conductivity type and located laterally with respect to said active region.

14. The method of claim 12, said electrons have an effective temperature below the temperature corresponding to the energy of said barrier layers.

15. The method of claim 11, wherein substantially all of said electrons are cool electrons with respect to said active region.

16. A method for injecting electrons into a semiconductor device having an active region comprising the steps of:
providing a source of electrons; and
injecting said electrons laterally into said active region, wherein said electrons have an effective temperature which is between 1 and 2 times the temperature of said active region lattice.

17. The method of claim 16, wherein said injected electrons are injected into a material having a first conductivity type and located laterally with respect to said active region.

18. The method of claim 16, wherein said electrons are effectively cool electrons with respect to said active region.

19. The method of claim 11, wherein substantially all of said electrons are cool electrons with respect to said active region.

20. A semiconductor device comprising:
an active region having photon emission energy level; and
an injection region for injecting electrons at a predetermined energy level into said active region, said predetermined energy level corresponding to an energy level associated with the recombination of electrons with holes in said active region.

21. The semiconductor device of claim 20, wherein said injection region injects said electrons laterally into said active region.

22. The semiconductor device of claim 21, wherein said injection region comprises a material having a first conductivity type and located laterally with respect to said active region.

23. The semiconductor device of claim 20, wherein said electrons are effectively cool electrons with respect to said active region.

24. The semiconductor device of claim 20, wherein substantially all of said electrons are cool electrons with respect to said active region.

25. A semiconductor device comprising:
an active region having photon emission energy level; and
an injection region for injecting electrons, said injection region comprising a first region having a first conductivity type and a second region having a second conductivity type said first region disposed laterally from said active region by less than or equal to 50 nm and said second region disposed distal from said first region and laterally disposed from said active region by less than or equal to 50 nm.

26. The semiconductor device of claim 25, wherein said electrons are effectively cool electrons with respect to said active region.

27. The semiconductor device of claim 25, wherein substantially all of said electrons are cool electrons with respect to said active region.
